(19) United States
(12) Patent Application Publication
(10) Pub. No.: US 2011/0083724 A1
(43) Pub. Date: Apr. 14, 2011

(54) Monolithic Integration of Photovoltaic Cells

(76) Inventor: Stanford R. Ovshinsky, Bloomfield Hills, MI (US)

(21) Appl. No.: 12/575,889

(22) Filed: Oct. 8, 2009

(51) Int. Cl. H01L 31/05; H01L 31/0232; H01L 31/18

(52) U.S. Cl. 136/249; 136/252; 438/72; 257/E31.127

(57) ABSTRACT

A photovoltaic device and method of forming a photovoltaic device. The photovoltaic device includes a fluorine-containing photovoltaic material and a transparent electrode. Inclusion of fluorine in the photovoltaic material increases its thermal stability. The effect is particularly pronounced in photovoltaic materials based on disordered forms of silicon, including amorphous, nanocrystalline, or microcrystalline silicon. The higher thermal stability permits deposition or annealing of the transparent electrode at high temperature. As a result, high conductivity is achieved for the transparent electrode without degrading the photovoltaic material. The higher conductivity of the transparent electrode facilitates series integration of individual devices to form a module. The method includes forming a photovoltaic material from a fluorinated precursor or treating a photovoltaic material in a fluorine-containing ambient.

### FIELD OF INVENTION

This invention relates to the high speed manufacturing of photovoltaic devices. More particularly, this invention relates to formation and integration of solar cells from photovoltaic materials in a continuous manufacturing process. Most particularly, this invention relates to the continuous deposition of silicon-based photovoltaic cells formed by a process that includes a high temperature step for forming a transparent conducting electrode.

### BACKGROUND OF THE INVENTION

Concern over the depletion and environmental impact of fossil fuels has stimulated strong interest in the development of alternative energy sources. Significant investments in areas such as batteries, fuel cells, hydrogen production and storage, biomass, wind power, algae, and solar energy have been made as society seeks to develop new ways of creating and storing energy in an economically competitive and environmentally benign fashion. The ultimate objective is to minimize society's reliance on fossil fuels and to do so in an economically competitive way that minimizes greenhouse gas production.

A number of experts have concluded that to avoid the serious consequences of global warming, it is necessary to maintain CO₂ at levels of 550 ppm or less. To meet this target, based on current projections of world energy usage, the world will need 17 TW of carbon-free energy by the year 2050 and 33 TW by the year 2100. The estimated contribution of various carbon-free sources toward the year 2050 goal are summarized below:

| Source | Projected Energy Supply (TW) |
|---|---|
| Wind | 2-4 |
| Tidal | 2 |
| Hydro | 1.6 |
| Biofuels | 5-7 |
| Geothermal | 2-4 |
| Solar | 600 |

Based on the expected supply of energy from the available carbon-free sources, it is apparent that solar energy is the only viable solution for reducing greenhouse emissions and alleviating the effects of global climate change.

Unless solar energy becomes cost competitive with fossil fuels, however, society will lack the motivation to eliminate its dependence on fossil fuels and will refrain from adopting solar energy on the scale necessary to meaningfully address global warming. As a result, current efforts in manufacturing are directed at reducing the unit cost (cost per kilowatt-hour) of energy produced by photovoltaic materials and products.

One strategy for decreasing the unit cost of energy from photovoltaic products is to reduce process costs by increasing process speeds. Process speed can be improved by increasing the intrinsic deposition rates of the different materials and layers used in the photovoltaic device structure. S. R. Ovshinsky has recently presented a breakthrough in the deposition rate of materials in the amorphous silicon system by describing a method that achieves deposition rates of several hundred angstroms per second. The method involves a pre-selection of preferred deposition species in a plasma deposition process and delivery of the preferred deposition species in relatively pure form to a deposition process. By removing deleterious species normally present in the plasma activation of silane, germane, and other common deposition precursor, S. R. Ovshinsky has demonstrated a remarkable increase in deposition rate without sacrificing photovoltaic performance by insuring that nearly defect-free material forms in the as-deposited state. (See, for example, U.S. patent application Ser. No. 12/199,656.)

Process speed can also be improved by adopting a continuous, instead of batch, manufacturing process. S. R. Ovshinsky has innovated the automated and continuous manufacturing techniques needed to produce thin film, flexible large-area solar panels based on amorphous, nanocrystalline, microcrystalline, polycrystalline or composite materials. Although his work has emphasized the silicon and germanium systems, the manufacturing techniques that he has developed are universal to all material systems. Representative contributions of S. R. Ovshinsky to the field of photovoltaic manufacturing are included in U.S. Pat. No. 4,400,409 (describing a continuous manufacturing process for making thin film photovoltaic films and devices); U.S. Pat. No. 4,410,588 (describing an apparatus for the continuous manufacturing of thin film photovoltaic solar cells); U.S. Pat. No. 4,438,723 (describing an apparatus having multiple deposition chambers for the continuous manufacturing of multilayer photovoltaic devices); and U.S. Pat. No. 5,324,553 (microwave deposition of thin film photovoltaic materials).

A second strategy for decreasing the unit cost of energy from photovoltaic products is to improve the photovoltaic efficiency of the device structure. Photovoltaic efficiency can be improved by engineering the chemical and physical properties of the active photovoltaic material to achieve new materials with superior performance. Crystalline silicon is currently the dominant photovoltaic material because of its wide availability in bulk form and mature manufacturing infrastructure. Crystalline silicon, however, possesses weak absorption of solar energy because it is an indirect gap material. Photovoltaic modules made from crystalline silicon thus require thick layers to achieve sufficient absorption of solar energy. The thick layers lead to modules that are bulky, rigid and not amenable to applications requiring lightweight, thin film products.

Materials with better absorption of the solar spectrum than crystalline silicon are under active development for photovoltaic products. Representative materials include CdS, CdSe, CdTe, ZnTe, CIGS (Cu—In—Ga—Se and related alloys), organic materials (including organic dyes), and TiO₂. These materials offer the prospect of reduced material costs because their strong solar absorption permits photovoltaic operation with thin films, thus reducing the volume of material needed to manufacture devices.

Amorphous silicon (and hydrogenated and/or fluorinated forms thereof) is another attractive photovoltaic material for efficient lightweight, and flexible thin-film photovoltaic products. Stanford R. Ovshinsky is a leading figure in thin film amorphous silicon science and technology. Early on, he recognized the advantages of amorphous silicon (as well as amorphous germanium, amorphous alloys of silicon and germanium, including doped, hydrogenated and fluorinated versions thereof) as a solar energy material. He also recognized the advantages of nanocrystalline silicon and was among the first to understand the physics and practical benefits of intermediate range order materials and multilayer photovoltaic devices. For representative contributions of S. R. Ovshinsky in the area of photovoltaic materials see U.S. Pat. No. 4,217,374 (describing suitability of amorphous silicon and related materials as the active material in several semiconducting devices); U.S. Pat. No. 4,226,898 (demonstration of solar cells having multiple layers, including n- and p-doped); and U.S. Pat. No. 5,103,284 (deposition of nanocrystalline silicon and demonstration of advantages thereof); as well as his article entitled “The material basis of efficiency and stability in amorphous photovoltaics” (Solar Energy Materials and Solar Cells, vol. 32, p. 443-449 (1994)).

Photovoltaic efficiency can also be improved through the design of the photovoltaic product. Efficiency depends not only on the characteristics of the photovoltaic material (absorption efficiency, quantum efficiency, carrier lifetime, and carrier mobility), but also on the surrounding device structure. In addition to efficient production of photogenerated charge carriers from the active photovoltaic material, high photovoltaic efficiency requires efficient extraction of the photogenerated carriers from the active photovoltaic material to the outer contacts of the photovoltaic product used to provide power to an external load. To maximize performance, it is necessary to recover the highest possible fraction of photogenerated carriers and to minimize losses in energy associated with transporting photogenerated carriers to the outer contacts. Accordingly, it is desirable to maximize both the photovoltaic current and voltage.

Higher operational voltages for photovoltaic products tend to reduce losses associated with carrier transport and delivery of power to external loads. Due to intrinsic recombination processes, however, the maximum output voltage available from a particular photovoltaic material is below the voltage preferred for minimizing power losses. To overcome this problem, it is common to integrate several photovoltaic devices in a series configuration to boost the output voltage of the photovoltaic product. The simplest approach to series integration entails producing multiple standalone photovoltaic modules, where each module includes an active area of photovoltaic material interposed between two outer contacts, and joining the outer contacts of the individual modules in series. This approach, however, suffers from the drawback that it is difficult to automate and has proven costly to incorporate into a manufacturing process. This approach also becomes more difficult to implement as the active area of the photovoltaic material decreases due to the need to join ever smaller contacts.

An alternative approach to series integration is a process known as monolithic integration. In monolithic integration, series integration is achieved by first patterning the photovoltaic material within a given module to form a series of small area photovoltaic devices on the same wafer or substrate and then connecting the individual photovoltaic devices via a metallization or contacting scheme to selectively connect devices in a series configuration. Monolithic integration permits series integration of a large number of individual devices and leads to a significant output voltage for the module as a whole.

Effective series integration requires electrode or contacting materials that are sufficiently conductive. Conventional metal electrodes readily satisfy the conductivity requirement. Implementation of series integration to photovoltaic devices is complicated, however, by the need to use a transparent electrode in the device structure. A transparent electrode is necessary to permit transmission of incident solar energy to the active photovoltaic material. Since the active photovoltaic material is necessarily positioned between two electrodes, at least one of the electrodes must be transparent to achieve a functional device. Typically, a transparent conductive oxide material is used as the transparent electrode.

Although transparent conductive oxides can function as electrodes, their conductivity is much lower than that of conventional metal electrodes and as a result, effective series integration becomes more difficult to achieve. It is known that the conductivity of many transparent conductive oxides is higher when deposition occurs at higher temperatures or when a deposited transparent conductive oxide is subject to a high temperature annealing step. As a result, processes that can accommodate a high temperature transparent electrode deposition or annealing step offer the best opportunity for achieving monolithic integration.

The most convenient way to accommodate a high temperature transparent electrode step is to deposit the transparent electrode material before depositing layers in the device structure that are sensitive to high temperatures. Many active photovoltaic materials, for example, are susceptible to degradation if exposed to the temperatures needed to improve the conductivity of most transparent electrode materials to the point where effective monolithic integration becomes possible. If the transparent electrode material is deposited after a thermally sensitive active photovoltaic material, the temperature at which the transparent electrode can be processed will be limited and its conductivity will suffer as a result.

In order for deposition of the transparent electrode to occur before deposition of the active photovoltaic material, it is necessary to employ a transparent substrate. If the transparent electrode is formed directly on a transparent substrate and the active photovoltaic material is subsequently formed on the transparent electrode, the transparent electrode can be deposited at high temperature or thermally annealed without degrading the active photovoltaic material and a transmissive pathway to the active photovoltaic material exists for incident electromagnetic radiation through the transparent substrate and transparent electrode.

Glass is the most common transparent substrate material. Many glass compositions have high melting points and are thus stable at high temperatures. Transparent electrode materials can be formed or annealed on glass substrate at temperatures of several hundred degrees without damaging the glass substrate. Thermal CVD (chemical vapor deposition) is one example of a high temperature method for depositing transparent conductive oxides. Alternatively, a thin transparent conductive surface oxide composition can be directly integrated with the body of the glass during fabrication.

Glass, however, may be disadvantageous from the point of view of high speed manufacturing or product application because it tends to be susceptible to fracture or scratching during substrate transport and handling during device fabrication and in the field. To improve durability, a thick glass substrate can be used. The greater thickness, however, increases weight and makes glass unsuitable as a substrate material for applications, such as rooftop mounts, where structural integrity is sensitive to load. Many opaque materials (e.g. steel) are mechanically robust at thin dimensions, flexible, and compatible with high speed manufacturing processes.

If use of steel or other opaque substrate is desired, the transparent electrode of the photovoltaic device structure must be remote from the substrate and deposited after the active photovoltaic material to achieve the transmissivity of incident light to the active photovoltaic material needed for functionality. This requirement means that the active photovoltaic material is exposed to the temperatures used to deposit or anneal the transparent electrode material. If the active photovoltaic material is temperature sensitive, the processing temperature of the transparent electrode material may need to be lowered to avoid a reduction in the efficiency of photocarrier generation within the active photovoltaic material. The lower processing temperature, however, may reduce the conductivity of the transparent electrode and compromise the effectiveness of monolithic integration.

As indicated above, amorphous silicon and related materials are promising photovoltaic materials. It has been shown that the photoresponse of amorphous silicon can be improved by forming amorphous silicon in conditions of high hydrogen dilution to form hydrogenated amorphous silicon. It is believed that hydrogen passivates amorphous silicon by coordinating to dangling bonds. Dangling bonds are sites of coordination unsaturation that represent defects in the structure that act as recombination centers for capturing photogenerated charge carriers and removing them from the photocurrent produced by incident electromagnetic radiation. Coordination of hydrogen saturates the dangling bonds and eliminates them as defects. The photovoltaic efficiency of amorphous silicon is improved as a result.

The incorporation of hydrogen into amorphous silicon is an equilibrium process in which an equilibrium exists between solid phase hydrogenated amorphous silicon and a dissociated phase that includes non-hydrogenated amorphous silicon (or hydrogenated amorphous silicon with a reduced concentration of hydrogen) in the solid phase and hydrogen in the gas phase. Experiments indicate, however, that the equilibrium is temperature sensitive and shifts toward the dissociated phase as the temperature is increased. As a result, exposure of hydrogenated amorphous silicon (or related materials) to elevated temperatures promotes the release hydrogen from the material. If the temperature is sufficiently high, the concentration of hydrogen remaining in the material may be too low to adequately passivate defects and the performance of the material deteriorates as a result. Accordingly, the need for high processing temperatures to maximize the conductivity of transparent electrode materials conflicts with the need to protect hydrogenated amorphous silicon from high temperatures to insure retention of an adequate amount of hydrogen in the solid phase. These conflicting needs make it difficult to realize the benefits of monolithic integration in a photovoltaic technology based on amorphous silicon and related materials.

There is a need for an amorphous silicon material that can withstand the high processing temperatures required to achieve sufficiently high conductivity of a transparent electrode material in a monolithic integration scheme.

### SUMMARY OF THE INVENTION

This invention provides a photovoltaic device structure and a method for forming photovoltaic device structures.

The photovoltaic device structure includes a photovoltaic material and a transparent electrode. In one embodiment, the photovoltaic material is a fluorine-containing material. The fluorine-containing material may be a fluorinated form of silicon or an alloy of silicon. The silicon or silicon alloy material may be amorphous, nanocrystalline, or microcrystalline. In another embodiment, the photovoltaic device structure includes one or more p-i-n junctions, where the intrinsic layer is a photovoltaic material that contains fluorine. The intrinsic layer may be a fluorinated form of silicon or an alloy of silicon in an amorphous, nanocrystalline, or microcrystalline state.

The transparent electrode is a transparent conductive material such as a conductive oxide. Embodiments of transparent conductive materials include tin oxide (SnO₂), indium oxide (In₂O₃), ITO (indium tin oxide), zinc oxide (ZnO), zinc tin oxide (ZnSnO₃, Zn₂SnO₄), and cadmium tin oxide (Cd₂SnO₄). Transparent conductive materials may also be doped with elements such as F, Al, Ga, In, B, and Sn to boost conductivity.

Inclusion of fluorine in the photovoltaic material increases the bonding strength of the material and makes the photovoltaic material more robust and more stable at high temperatures. Deposition of the transparent electrode over an existing photovoltaic material can therefore be performed at higher temperatures without degrading the photovoltaic material. As a result, the conductivity of the transparent electrode is high and series integration of multiple devices is more readily achieved.

The photovoltaic device structure may also include a substrate, a back reflector layer, an overlying protective or encapsulating material, and conductive grid lines connected to the transparent electrode. The back reflector may be a conductive oxide, conductive chalcogenides, metal or combination thereof. Representative back reflectors include Ag, Al, ZnO, ZnS, ZnO/Ag, ZnS/Ag, ZnO/Al, and ZnS/Al.

The method includes formation of a photovoltaic material over a substrate and formation of a transparent conductive material over the photovoltaic material. The transparent conductive material is in electrical communication with the photovoltaic material and serves as a window through which transmission of incident solar or other electromagnetic radiation occurs. Formation of the photovoltaic material may be accomplished by a chemical vapor deposition, plasma-enhanced chemical vapor deposition, or physical vapor deposition process. In one embodiment, the photovoltaic material is formed in the presence of fluorine or with a fluorine-containing precursor. In another embodiment, the photovoltaic material is subjected to a post-deposition fluorination treatment.

In one embodiment, the transparent electrode is formed at a high deposition temperature. In another embodiment, the transparent electrode is formed at a low deposition temperature and subjected to a post-deposition annealing step. High temperature formation or thermal processing increases the conductivity of the transparent electrode, which promotes higher conversion efficiency for the photovoltaic device.

The method may further include deposition of a conductive material between the photovoltaic material and a substrate and deposition of n-type or p-type materials adjacent to the photovoltaic material. The conductive material may be a back reflector material or transparent material. One or more of the layers may also be patterned to form isolated regions which may be interconnected in series to form a photovoltaic module that includes a plurality of photovoltaic devices. Series interconnection may be achieved by laser welding or through masking and etching techniques.

The high conductivity achieved for the transparent electrode facilitates monolithic series integration of photovoltaic devices based on an amorphous silicon technology for the first time.

### BRIEF DESCRIPTION OF THE DRAWING

FIG. 1A depicts a photovoltaic device that includes a back reflector, an active photovoltaic material, and a transparent electrode.

FIG. 1B depicts a photovoltaic device that includes a back reflector, a p-i-n structure, and a transparent electrode.

FIG. 2 depicts a photovoltaic module that includes a plurality of photovoltaic devices of the type shown in FIG. 1B connected in series.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein and including embodiments that provide positive benefits for high-volume manufacturing, are also within the scope of this invention. Accordingly, the scope of the invention is defined only by reference to the appended claims.

As used herein, “on” signifies direct contact of a particular layer with another layer and “over” signifies that a particular layer is mechanically supported by another layer. If a particular layer, for example, is said to be formed on a substrate, the layer directly contacts the substrate. If a particular layer is said to be formed over a substrate, the layer is mechanically supported by the substrate and may or may not make direct contact with the substrate. If a particular layer is said to be formed on another layer, the particular layer directly contacts the other layer. If a particular layer is said to be formed over another layer, the particular layer is supported by the other layer and may or may not contact the other layer.

This invention provides a method of achieving monolithic integration of photovoltaic devices that include amorphous silicon or a related material as the active photovoltaic material. Monolithic integration is generally performed by patterning or segmenting the layers of photovoltaic structure to define a series of electrically isolated devices. The patterning includes the selective formation of features (e.g. trenches or vias) to spatially separate individual devices and define a pattern of contacts, and filling those features with a conductive material (or laser welding) to form contacts that achieve series integration of the individual devices. Each of several layers may be patterned and the patterns formed in the different layers can be offset or otherwise arranged to facilitate the formation of series connections between adjacent devices.

The method of the instant invention generally includes providing a substrate, forming a back reflector over the substrate, forming an active photovoltaic material over the back reflector, patterning the active photovoltaic material, and forming a transparent electrode over the photovoltaic material. Patterning of the active photovoltaic material includes forming a plurality of electrically isolated photovoltaic regions that may further be connected in series by the transparent electrode material to achieve monolithic integration. In one embodiment, the transparent electrode is formed at high temperature. In another embodiment, the transparent electrode is subjected to a high temperature annealing step after deposition. The method may further include deposition of additional layers, such as a back reflector layer or a protective layer.

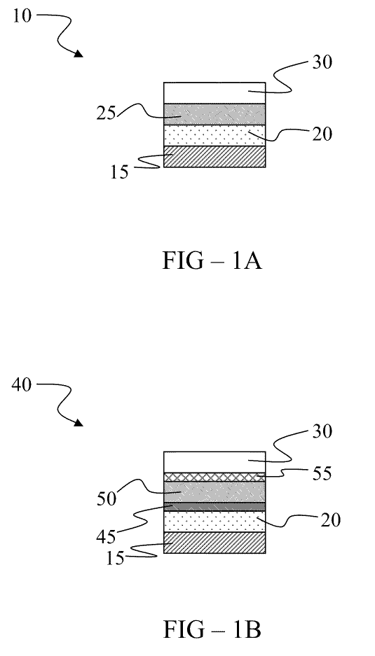

FIGS. 1A and 1B illustrate representative photovoltaic device structures in accordance with the instant invention. FIG. 1A shows a basic device structure 10 that includes substrate 15, back reflector 20, active photovoltaic material 25, and transparent electrode 30. FIG. 1B shows a device 40 based on a single p-i-n structure. A p-i-n structure is a sequence of layers that includes a p-type material, an intrinsic or i-type material, and an n-type material. A device, such as device 40, that includes a single p-i-n structure may be referred to as a single junction device. Device 40 includes substrate 15, back reflector 20, n-type layer 45, i-type layer 50 (which serves as the active photovoltaic material), p-type layer 55, and transparent electrode 30.

Substrate 15 is a mechanically stable material having sufficient durability to withstand the deposition conditions associated with the formation of the individual layers in the device structure. Substrate 15 may be a metal, metal alloy, composite, or plastic substrate. Representative substrates include steel, aluminum, silicon, Kevlar, Mylar, Kapton, polyimide, and polyethylene. Although the principles of the instant invention extend to transparent substrates (including glass and other oxide dielectrics), the benefits are expected to be greatest for opaque substrates. When substrate 15 is opaque, module 100 receives incident solar or electromagnetic radiation through transparent electrode 30.

Back reflector 20 serves as a reflector of solar or electromagnetic radiation that passes from transparent electrode 30 through active photovoltaic material 25 shown in FIG. 1A or the p-i-n device structure defined by layers 45, 50 and 55 shown in FIG. 1B. The portion of incident solar or electromagnetic radiation that is transmitted through active photovoltaic material 25 or p-i-n structure defined by layers 45, 50, and 55 is reflected by back reflector 20 and returned to the active photovoltaic material of the p-i-n structure to improve the efficiency of absorption to increase the current available from the device.

Back reflector 20 can be formed of any reflective material that is capable of conducting an electrical current. Back reflector 20 may be a single material or a composite material. Representative back reflector materials include aluminum (Al), silver (Ag), copper (Cu), conductive oxides, conductive chalcogenides (e.g. ZnS, ZnTe, ZnSe, CdS), or combinations thereof (e.g. a composite back reflector that includes a conductive oxide and a metal). Examples include ZnO, ZnO/Al, ZnO/Ag, Al₂O₃, Al₂O₃/Al, and Al₂O₃/Ag. The back reflector is preferably textured to facilitate light trapping and minimize scattering or reflection of radiation to the exterior of the device. The conductive oxides and conductive chalcogenides may be formed, for example, with a sputtering technique. Metallic back conductor materials are typically formed by sputtering or evaporation, but may be formed by other techniques known in the art as well.

Active photovoltaic material 25 may be any material capable of generating a photocurrent upon absorption of incident solar or electromagnetic radiation. Representative materials include CdS, CdSe, CdTe, ZnTe, ZnSe, ZnS, CIGS (Cu—In—Ga—Se and related alloys), organic materials (including organic dyes), and TiO₂ or other metal oxides, including doped or activated forms thereof. Silicon-based materials are another prominent class of active photovoltaic materials. Silicon-based materials include amorphous silicon (a-Si), alloys of amorphous silicon (e.g. amorphous silicon-germanium alloys), nanocrystalline silicon, nanocrystalline alloys of silicon, microcrystalline silicon, microcrystalline alloys of silicon. Silicon-based photovoltaic materials may also be rendered n-type or p-type through appropriate doping. Column III elements (e.g. B) are good p-type dopants and column V elements (e.g. P) are good n-type dopants. Multilayer photovoltaic materials may be formed from a combination of two or more of the foregoing photovoltaic materials, including two or more alloys that differ in the relative proportions of the constituent atoms.

The device structure shown in FIG. 1B may be expanded to include two or more p-i-n (or n-i-p) structures stacked in series between back reflector 20 and transparent electrode 30 to achieve multiple junction device structures. The tandem (dual junction) and triple junction cells known in the prior art, for example, include two and three p-i-n (or n-i-p) structures in series, respectively. For improved absorption of the solar spectrum, the bandgaps of the different intrinsic layers of multi junction devices may differ. Individual layers of single or multilayer device structures may also achieve bandgap tuning by incorporating graded compositions. Other multilayer device structures in accordance with the instant invention include pn devices or np devices.

Methods for forming active photovoltaic materials (or surrounding n-type or p-type layers) include a solution deposition process (e.g. sol-gel process), a chemical vapor deposition process (including MOCVD, PECVD (at radiofrequencies or microwave frequencies), or a physical vapor deposition process (e.g. evaporation, sublimation, sputtering).

Transparent electrode 30 is a material providing sufficient transmission of incident solar or electromagnetic radiation and adequate conductivity to insure efficient mobility of photogenerated charge carriers produced in the active photovoltaic material. Transparent electrode materials are conductive materials that transmit solar or other intended activating electromagnetic radiation and may also be referred to herein as transparent conductive materials. Transparent conductive materials are typically metal oxides prepared by a sputtering, reactive sputtering, solution deposition, pulsed laser deposition, spray pyrolysis, evaporation, or chemical vapor deposition technique. Representative transparent conductive materials include tin oxide (SnO₂), indium oxide (In₂O₃), ITO (indium tin oxide), zinc oxide (ZnO), zinc tin oxide (ZnSnO₃, Zn₂SnO₄), and cadmium tin oxide (Cd₂SnO₄). Transparent conductive materials may be doped with elements such as F, Al, Ga, In, B, and Sn to boost conductivity.

Device structures in accordance with the instant invention may further include grid electrodes placed in contact with or in electrical communication with the transparent electrode. Additional layers that may be present in the device structure include one or more protective layers, encapsulating layers, adhesive layers and/or laminate layers.

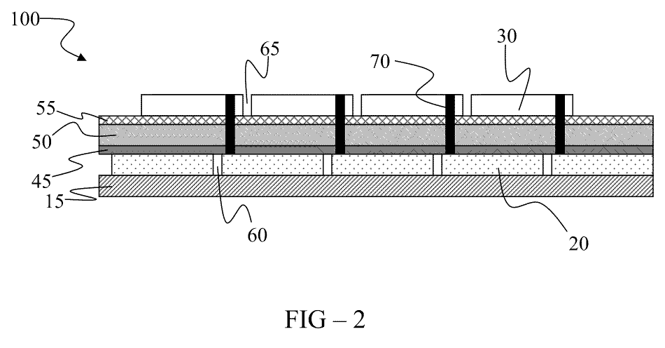

FIG. 2 shows a cross-sectional view of a representative photovoltaic module that includes several single junction photovoltaic devices of the type shown in FIG. 1B interconnected in a monolithic series configuration. Module 100 includes substrate 15 with back reflector 20 formed thereon. Back reflector 20 has been patterned to create electrically isolated regions separated by pattern lines 60. The electrically isolated regions ultimately demarcate the individual devices of the module. Patterning of back reflector 20 may be achieved, for example, by laser scribing. In one embodiment, laser scribing is accomplished with an excimer laser. Pattern lines 60 may also be formed by masking and etching techniques familiar to those in the art.

The individual layers of a single junction p-i-n device are next deposited in succession. The layers include n-type layer 45, i-type layer 50 and p-type layer 55. Transparent electrode 30 is formed over p-type layer 55 and patterned to form electrically isolated regions. Pattern lines 65 of transparent electrode 30 are formed generally parallel to, but are offset from, pattern lines 60 of back reflector 20. Pattern lines 65 may be formed by laser scribing using an excimer or other ablative laser. The power of the laser, wavelength, depth of focus, and exposure time are carefully controlled to ablate transparent electrode 30 without affecting the underlying layers of the p-i-n device structure. Pattern lines 65 may also be formed by masking and etching techniques familiar to those in the art. If desired, a protective or encapsulating layer (not shown in FIG. 2) may be formed over transparent electrode 30.

The isolated device regions are next interconnected in series by laser welding transparent electrode 30 to back reflector 20. Laser welds 70 are positioned between pattern lines 60 formed in back reflector 20 and pattern lines 65 formed in transparent electrode 30. Laser welding may be achieved, for example, with a Nd³HYAG laser. Laser welding connects the lower contact of one device to the upper contact of a neighboring device to form a series-connected module. As used herein, the lower contact of a device is the electrical contact in closest proximity to the substrate and the upper contact of a device is the electrical contact positioned further from the substrate. The lower contact is proximate to the substrate and the upper contact is distal to the substrate. In the embodiment shown in FIG. 2, back reflector 20 serves as the lower contact and transparent electrode 30 serves as the upper contact.

A key consideration in monolithic integration is the conductivity of the transparent electrode. In large area integrated systems, photogenerated charge carriers need to migrate over long distances through the transparent electrode to reach an outer contact or grid line for delivery of current to an external device. If the conductivity of the transparent electrode is poor, appreciable resistive losses will occur and the overall efficiency of the device is decreased significantly.

The conductivity of transparent conductive materials varies with the chemical composition of the material. Tin oxide and indium-tin oxide are among the most conductive of the transparent conductive materials. The conductivity of transparent conductive materials also depends on the temperature of deposition or temperature of post-deposition thermal treatment. The deposition temperature (or temperature of the deposition surface on which a transparent conductive material is deposited) or post-deposition treatment temperature must be kept sufficiently high to insure adequate conductivity of a transparent conductive material. If the temperature of deposition or post-deposition thermal treatment is too low, the conductivity of the transparent conductive material is reduced. If the surface temperature or annealing temperature is too high, however, the transparent conductive material becomes thermally unstable and decomposes or degrades in quality. Accordingly, an optimal temperature can be identified for any particular transparent conductive material that maximizes its conductivity. The optimal deposition or post-deposition thermal treatment temperature for tin oxide and indium-tin oxide, for example, is typically above 500° C.

When the transparent conductive material is formed over other layers in a photovoltaic device structure, the need for an elevated deposition or post-deposition processing temperature necessitates subjecting these other layers to the elevated temperature. If any of these other layers are unstable or susceptible to degradation at the elevated temperature, the benefits achieved in optimizing the conductivity of the transparent conductive material may be offset by a deterioration in the performance of other layers in the photovoltaic device structure. In the device structure shown in FIG. 1B, for example, transparent electrode 30 is formed over substrate 15, back reflector 20, n-type layer 45, i-type layer 50, and p-type layer 55. If any of these constituents deteriorates at the elevated temperature required to optimize the conductivity of transparent electrode 30, the overall device performance may suffer even though the conductivity of transparent electrode 30 has been improved.

Concerns over thermal sensitivity are particularly acute for photovoltaic materials based on amorphous silicon. Unlike crystalline silicon, amorphous silicon is a highly disordered material that lacks regular tetrahedral bonding of silicon atoms. In crystalline silicon, the three-dimensional coordination requirements are met because of the sufficient availability of atoms during deposition, ability of atoms to arrange in three dimensions, and the equilibrium nature of the widely-used Czochralski growth process. An equilibrium growth process allows for the atom mobility necessary to establish a regular tetrahedral bonding geometry.

Deposition of amorphous silicon, in contrast, is a non-equilibrium growth process that inhibits the structural relaxation and atomic mobility necessary for silicon to achieve regular tetrahedral coordination. The structure of amorphous silicon is kinetically “frozen”, or inhibited, from achieving the thermodynamically most stable regular tetrahedral coordination that occurs in crystalline silicon. As a result, the structure of amorphous silicon is characterized by a random continuous distribution of bond angles, bond lengths and distortions from regular tetrahedral coordination. The deviations from regular tetrahedral coordination constitute structural defects in amorphous silicon. Defects also include dangling bonds, which are sites of coordination unsaturation where the coordination of silicon is two-fold (dihydride defects) or three-fold (trihydride defects) instead of fourfold. The structural and coordination defects in amorphous silicon result in the presence of electronic states in the band gap that can act as non-radiative recombination centers that reduce photoconversion efficiency and impede carrier mobility.

A common strategy for reducing the concentration of defects in amorphous silicon is to deposit the material via a plasma-enhanced chemical deposition process from silane in an environment highly diluted with hydrogen. High hydrogen dilution has been shown to markedly improve the quality of amorphous silicon by passivating defects, saturating dangling bonds, removing non-tetrahedral structural distortions, and relieving bond strain. High hydrogen dilution has also been shown to improve the characteristics of amorphous alloys of silicon and germanium.

Despite its beneficial effect on the electronic and optical properties of amorphous silicon, high hydrogen dilution has the detrimental effect of impairing thermal stability. It has been shown, for example, that the temperature at which hydrogen evolves from amorphous silicon decreases with increasing hydrogen dilution during deposition. At low hydrogen dilution, most of the hydrogen present in amorphous silicon evolves at a temperature of ˜500° C. At high hydrogen dilution, the peak hydrogen evolution temperature decreases to ˜400° C., with incipient hydrogen evolution (and onset of degradation of the material) occurring at temperatures of ˜250° C. As hydrogen evolves, the properties of hydrogenated amorphous silicon degrade and the efficiency of solar cells based on hydrogenated amorphous silicon is reduced. To preserve the beneficial effect of hydrogen, it is therefore necessary to insure that hydrogenated amorphous silicon is not exposed to post-deposition temperatures that are high enough to promote hydrogen evolution.

The sensitivity of amorphous silicon to thermally-induced hydrogen evolution limits the temperature of process steps that occur after deposition of amorphous silicon. In photovoltaic device structures formed on opaque substrates, a transparent electrode is necessarily formed after the active photovoltaic material. When the active photovoltaic material is based on hydrogenated amorphous silicon, the transparent conductive material used to form the upper electrode (the electrode remote from the substrate) must therefore be formed at a temperature below the temperature of hydrogen evolution. To realize the benefits of hydrogen dilution, it is therefore necessary to deposit the transparent conductive material at temperatures safely below ˜250° C. Since temperatures above ˜300° C. are necessary to optimize the conductivity of the most viable transparent conductive materials, the efficiency of photovoltaic devices made from amorphous silicon formed at conditions of high hydrogen dilution is necessarily sacrificed. In practice, low temperature methods such as evaporation or sputtering, which are performed at temperatures below 100° C., are used to deposit transparent conductive materials over amorphous silicon layers that have been formed at conditions of high hydrogen dilution.

This invention provides a way to realize the benefits of both high quality amorphous silicon and a highly conductive transparent electrode. Instead of using hydrogen, this invention uses fluorine to passivate defects, saturate dangling bonds, and improve the structure of amorphous silicon. Like hydrogen, fluorine can terminate dangling bonds and promote regular tetrahedral bonding of silicon. Because the Si—F bond strength is much higher than the Si—H bond strength, however, the thermal stability of amorphous silicon is much less affected by fluorination than by hydrogenation. Because of a higher bond strength, the Si—F bonds that terminate the dangling of amorphous silicon are much less susceptible to cleavage (thermal or chemical) than Si—H bonds. As a result, when fluorine is used to reduce the concentration of defects in amorphous silicon, the resulting material is stable at higher temperatures than is an amorphous silicon material formed at conditions of high hydrogen dilution.

In one embodiment, fluorinated photovoltaic materials may be formed from a fluorine-containing deposition precursor. Representative fluorine-containing precursors for photovoltaic materials based on silicon, germanium, and silicon-germanium alloys include SiFₓH₄, (SiF₄, SiF₃H, SiF₂H₂, SiFH₃) and GeFₓH₄, (GeF₄, GeF₃H, GeF₂H₂, GeFH₃). Fluorine-containing deposition precursors may also include alkyl (e.g. methyl, ethyl, propyl, butyl) groups or halogens (e.g. chlorine or bromine). These precursors may be employed in chemical vapor deposition or related deposition processes (including plasma-enhanced chemical vapor deposition) to form silicon, germanium, and silicon-germanium alloys in an amorphous, nanocrystalline, or microcrystalline state.

In another embodiment, fluorinated photovoltaic materials may be formed from a non-fluorinated precursor in the presence of a fluorine-containing additive. Precursors such as SiH₄, Si₂H₆, GeH₄, and Ge₂H₆ are commonly employed in vapor deposition processes to form photovoltaic materials based on silicon and/or germanium. Inclusion of a fluorine-containing additive gas in the deposition leads to incorporation of fluorine in the product material and permits realization of the benefits associated with fluorine described hereinabove. Fluorine-containing additive gases include F₂, HF, CF₄, SF₆, and BF₃. The fluorine-containing additive gas may also provide n-type or p-type doping.

In another embodiment, a photovoltaic material is deposited in the absence of a fluorinated precursor or a fluorine-containing additive and subjected to a post-deposition fluorination treatment. The fluorination treatment includes exposing the photovoltaic material to an ambient environment that contains fluorine. The ambient may include a fluorine-containing gas such as F₂, HF, CF₄, SF₆, and BF₃. Alternatively, the ambient may include a fluorine-containing liquid such as HF or a fluorinated organic compound, such as a fluorinated alkane or fluorinated alkene. The fluorine-containing liquid may be in direct contact with the photovoltaic material. The fluorination process may be performed at conditions of elevated temperature or elevated pressure.

The improved thermal stability of fluorine-containing amorphous silicon means that subsequent deposition of a transparent conductive material to form a transparent electrode can occur at higher temperatures without degrading the active photovoltaic material. As a result, highly conductive transparent electrodes can be formed without sacrificing the conversion efficiency of the active photovoltaic material and monolithic integration of a plurality of individual photovoltaic devices is more readily achieved.

In one embodiment, the transparent conductive material is formed at a temperature above 250° C. In another embodiment, the transparent conductive material is formed at a temperature above 300° C. In still another embodiment, the transparent conductive material is formed at a temperature above 350° C. In yet another embodiment, the transparent conductive material is formed at a temperature above 400° C. In a further embodiment, the transparent conductive material is formed at a temperature above 500° C.

The higher available deposition temperatures mean that methods such as chemical vapor deposition can be used to form the transparent conductive material. It is no longer necessary to limit deposition of the transparent conductive material to low temperature techniques such as solution deposition, sputtering, or evaporation. Conductive metal oxides, for example, can be formed at high temperature from reactions of metal alkyl compounds or metal halide compounds in the presence of oxygen or an oxygen-containing gas.

As an alternative to utilizing a high deposition temperature, the transparent conductive material can be formed at a low deposition temperature and subsequently annealed at a higher temperature to increase its conductivity. In one embodiment, the transparent conductive material is annealed at a temperature above 250° C. In another embodiment, the transparent conductive material is annealed at a temperature above 300° C. In still another embodiment, the transparent conductive material is annealed at a temperature above 350° C. In yet another embodiment, the transparent conductive material is annealed at a temperature above 400° C. In a further embodiment, the transparent conductive material is annealed at a temperature above 500° C.

The principles of the instant invention extend to both batch and continuous web manufacturing. In batch processing, deposition of one or more layers of a photovoltaic device occurs sequentially on individual wafers or substrates. Each wafer or substrate is handled separately and generally has a maximum lateral dimension on the order of several inches to a few feet. In batch processing, the wafer or substrate is commonly held stationary during deposition of a particular layer.

In continuous web deposition, the substrate is a mobile, extended web that is continuously conveyed through a series of deposition or processing units. The web typically has a dimension of a few inches to a few feet in the direction transverse to the direction of transport of the web through the manufacturing apparatus and a dimension of a few hundred to a few thousand feet in the direction of web transport. In continuous manufacturing, the web is generally in motion during deposition and processing of the individual layers of a multilayer device. The web of substrate material may be continuously advanced through a succession of one or more operatively interconnected, environmentally protected deposition chambers, where each chamber is dedicated to the deposition of a particular layer or layers of a photovoltaic device structure onto either the web or a layer previously deposited on the web. The series of chambers may also include chambers dedicated to processes such as patterning, heating, annealing, cleaning, or substrate removal. By making multiple passes through the succession of deposition chambers, multiple layers of various configurations (including patterned or unpatterned layers as described hereinabove) may be obtained.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. A method for forming a photovoltaic device comprising:
forming a photovoltaic material, said photovoltaic material comprising fluorine; and
forming a transparent conductive material in electrical communication with said photovoltaic material.

2. The method of claim 1, wherein said forming photovoltaic material comprises depositing said photovoltaic material from a first gas, said first gas comprising fluorine.

3. The method of claim 1, wherein said first gas further comprises silicon or germanium.

4. The method of claim 3, wherein said first gas further comprises hydrogen, a halogen, or an alkyl group.

5. The method of claim 2, wherein said first gas further comprises boron, carbon, sulfur, or phosphorous.

6. The method of claim 2, wherein said forming photovoltaic material further comprises depositing said photovoltaic material from a second gas.

7. The method of 6, wherein said second gas comprises silicon or germanium.

8. The method of claim 7, wherein said second gas further comprises hydrogen or fluorine.

9. The method of claim 1, wherein said forming photovoltaic material comprises exposing said photovoltaic material to a fluorine-containing ambient.

10. The method of claim 9, wherein said fluorine-containing ambient includes a fluorine-containing gas.

11. The method of claim 9, wherein said fluorine-containing ambient includes a fluorine-containing liquid.

12. The method of 11, wherein said fluorine-containing liquid is an acid.

13. The method of 11, wherein said fluorine-containing liquid is a fluorinated organic compound.

14. The method of claim 13, wherein said fluorinated organic compound is a fluorinated alkane.

15. The method of claim 9, wherein said fluorine-containing ambient is heated to a temperature above room temperature.

16. The method of claim 1, wherein said forming photovoltaic material comprises forming said photovoltaic material in a plasma process.

17. The method of claim 16, wherein said plasma process is plasma-enhanced chemical vapor deposition.

18. The method of claim 1, wherein said transparent conductive material comprises a transparent conductive oxide.

19. The method of claim 18, wherein said transparent conductive oxide comprises a transparent metal oxide.

20. The method of claim 18, wherein said transparent conductive oxide comprises Sn, Zn, or In.

21. The method of claim 1, wherein said transparent conductive material is formed after said photovoltaic material.

22. The method of claim 21, wherein said transparent conductive material is formed at a temperature of at least 250° C.

23. The method of claim 21, wherein said transparent conductive material is formed at a temperature of at least 300° C.

24. The method of claim 21, wherein said transparent conductive material is formed at a temperature of at least 400° C.

25. The method of claim 21, wherein said transparent conductive material is formed at a temperature of at least 500° C.

26. The method of claim 21, wherein said transparent conductive material directly contacts said photovoltaic material.

27. The method of claim 1, wherein said photovoltaic material is an intrinsic semiconductor.

28. The method of claim 27, further comprising forming an n-type layer, said n-type layer being disposed between said photovoltaic material and said transparent conductive material.

29. The method of claim 28, wherein said n-type layer is formed from a gas phase precursor, said gas phase precursor comprising silicon.

30. The method of claim 27, further comprising forming a p-type layer, said p-type layer being disposed between said photovoltaic material and said transparent conductive material.

31. The method of claim 30, wherein said p-type layer is formed from a gas phase precursor, said gas phase precursor comprising silicon.

32. The method of claim 1, further comprising providing a substrate, said photovoltaic material being formed over said substrate.

33. The method of claim 32, further comprising forming a back reflector, said back reflector being disposed between said substrate and said photovoltaic material.

34. The method of claim 33, wherein said back reflector comprises a metal oxide.

35. The method of claim 34, wherein said back reflector further comprises a metal.

36. The method of claim 33, further comprising patterning said back reflector to form a plurality of electrically isolated regions of said back reflector.

37. The method of claim 36, further comprising patterning said transparent conductive material to form a plurality of electrically isolated regions of said transparent conductive material, said plurality of electrically isolated regions of said transparent conductive material defining a plurality of photovoltaic devices, each of said photovoltaic devices including an electrically isolated region of said back reflector, said photovoltaic material, and an electrically isolated region of said transparent conductive material.

38. The method of claim 37, further comprising connecting two or more of said photovoltaic devices in series.

39. The method of claim 38, wherein said connecting includes laser welding.

40. The method of claim 38, wherein said connecting includes masking and etching.

41. The method of claim 37, further comprising patterning said photovoltaic material to form a plurality of electrically isolated regions of said photovoltaic material, said plurality of electrically isolated regions of said photovoltaic material defining a plurality of electrically isolated photovoltaic devices, each of said electrically isolated photovoltaic devices including an electrically isolated region of said back reflector, an electrically isolated region of said photovoltaic material, and an electrically isolated region of said transparent conductive material.

42. The method of claim 41, further comprising connecting said electrically isolated photovoltaic devices in series.

43. The photovoltaic device formed by the method of claim 1.

44. A method of forming a photovoltaic module comprising:
providing a metal substrate; and
forming a monolithically integrated plurality of photovoltaic devices on said substrate.

45. The method of claim 44, wherein said each of said plurality of photovoltaic devices includes a photovoltaic material, said photovoltaic material comprising silicon.

46. The method of claim 45, wherein said silicon comprises amorphous silicon.

47. The method of claim 45, wherein said photovoltaic material further comprises fluorine.

48. The method of claim 45, wherein each of said photovoltaic devices further comprises a transparent conductive material, said transparent conductive material being formed at a temperature of at least 250° C.

49. The product of the method of claim 44.
